(19) United States
(12) Patent Application Publication
(10) Pub. No.: US 2021/0046704 A1
(43) Pub. Date: Feb. 18, 2021

(54) ADJUSTABLE PRINT BED FOR 3D PRINTING

(71) Applicants: ARCTIC BIOMATERIALS OY, Tampere (FI); MINIFACTORY OY LTD, Seinäjoki (FI)

(72) Inventors: Mikko HUTTUNEN, Tampere (FI); Janne PIHLAJAMÄKI, Seinäjoki (FI)

(21) Appl. No.: 16/964,060

(22) PCT Filed: Jan. 23, 2018
(86) PCT No.: PCT/FI2018/050053

§ 371 Date: Jul. 22, 2020

(51) Int. Cl. B29C 64/245; B29C 64/232; B29C 64/393; B29C 64/118; B33Y 10/00; B33Y 30/00

(52) U.S. Cl. CPC B29C 64/245; B29C 64/232; B29C 64/393; B33Y 50/02; B33Y 10/00; B33Y 30/00; B29C 64/118

(57) ABSTRACT

According to an aspect, there is provided a pin board tool for facilitating three-dimensional (3D) scanning and printing, comprising: an array (301) of parallel pins, wherein the parallel pins in the array are aligned in the longitudinal direction when the pin board tool is empty; a fixture (303) holding the array; and locking means (302) configured to lock the array of parallel pins in place when activated to provide a print bed for 3D printing an object having a surface corresponding to a pattern formed by the array locked in place, wherein the parallel pins are configured to be able to move freely in a longitudinal direction of the parallel pins independent of each other within a movement range when the locking means are inactive and an object is pushed against the parallel pins, the movement range being equal to or smaller than a length of each parallel pin. The application further relates to a 3D scanning and printing system (300) and also to a method for three dimensional (3D) scanning and printing.

### FIELD OF THE INVENTION

The present invention relates to 3D scanning and printing of objects and specifically for facilitating the 3D scanning and printing of objects by reducing the need for support materials.

### BACKGROUND

The following background description art may include insights, discoveries, understandings or disclosures, or associations together with disclosures not known to the relevant art prior to the present invention but provided by the present disclosure. Some such contributions disclosed herein may be specifically pointed out below, whereas other such contributions encompassed by the present disclosure the invention will be apparent from their context.

3D printing refers to a process where a three-dimensional object is created based on a three-dimensional computer model of said object. The three-dimensional computer model may have been created, for example, using a computer-aided design (CAD) package or a 3D scanner. 3D printing has found applications in a plethora of fields in ranging from creating custom parts for cars and rapid prototyping for industry or research to medical applications.

One popular example of a medical application for which 3D printing may be used is manufacturing orthopaedic casts to support fracture healing. Most casts are still prepared in a conventional way from a cotton bandage that has been combined with plaster (also known as plaster of Paris or gypsum plaster), which hardens after it has been made wet. While plaster casts are widely used, they have several notable limitations. Plaster casts usually render the limb unreachable during treatment which causes the skin under plaster to become dry and scaly. Moreover, they are relatively heavy, may break down if they get wet and cannot be removed without breaking the cast. 3D printed casts may overcome many or all of the aforementioned limitations.

Usually, the process of preparing a 3D printed cast starts by taking a 3D surface scan of the body part of interest. Additional medical scans may also be performed such as an x-ray scan, a computed tomography (CT) scan or a magnetic resonance imaging (MRI) scan. Moreover, the final design for the cast may be still, in some case, prepared manually based on the performed scans. The 3D printing itself may use, for example, fused filament fabrication (FFF) technique where a continuous filament of a thermoplastic material is deposited through the nozzle of the print head, typically in layers, to form the 3D printed object or a laser sintering technique where a high-power laser is used to sinter powdered material, binding the material together to form a solid 3D structure.

There are, however, several limitations to the current techniques used for 3D printing casts. The mechanical properties of 3D printed objects manufactured by using the fused filament fabrication technique are limited due to the fact that these objects are typically composed of polymer only. On the other hand, laser sintering techniques require the use of expensive, high-powered lasers meaning that these techniques are not as readily available to many as other 3D printing techniques. Furthermore, most current 3D printing processes used for this particular application share the disadvantage of requiring relatively long manufacturing time. For example, 3D printing of a cast using conventional fused filament deposition technique may take several hours up to several days. In some situations, the majority of printing time is consumed by the 3D printing of the support structures, which are removed from the final 3D printed cast which may also take considerable amount of time. Therefore, minimizing the need for support structures would lead to reduced 3D printing time as well as to reduced volume for the 3D printed part and considerably improve the feasibility of 3D printing for this particular application.

### SUMMARY

The following presents a simplified summary of features disclosed herein to provide a basic understanding of some exemplary aspects of the invention. This summary is not an extensive overview of the invention. It is not intended to identify key/critical elements of the invention or to delineate the scope of the invention. Its sole purpose is to present some concepts disclosed herein in a simplified form as a prelude to a more detailed description.

According to an aspect, there is provided the subject matter of the independent claims. Embodiments are defined in the dependent claims.

One or more examples of implementations are set forth in more detail in the accompanying drawings and the description below. Other features will be apparent from the description and drawings, and from the claims.

### BRIEF DESCRIPTION OF THE DRAWINGS

In the following the invention will be described in greater detail by means of preferred embodiments with reference to the attached drawings, in which

FIG. 1 illustrates a 3D scanner/printer system according to an exemplary embodiment of the invention;

FIG. 2 illustrates a 3D scanner/printer system according to an exemplary embodiment of the invention;

FIG. 3 illustrates a 3D scanner/printer system according to an exemplary embodiment of the invention;

FIG. 4 illustrates a pair of pin board tools according to an exemplary embodiment of the invention;

FIG. 5 illustrates a clamping mechanism according to an exemplary embodiment of the invention;

FIG. 6 illustrates a 3D scanner/printer system according to an exemplary embodiment of the invention;

FIG. 7 illustrates a pin board tool according to an exemplary embodiment of the invention;

FIGS. 8 and 9 illustrate a locking mechanism of a pin board tool according to an exemplary embodiment of the invention;

FIG. 10 illustrates a pin board tool according to an exemplary embodiment of the invention;

FIG. 11 is a flow diagram illustrating a 3D scanning/printing process according to an exemplary embodiment of the invention; and

FIG. 12 illustrates a control computer according an embodiment of the invention.

### DETAILED DESCRIPTION OF THE INVENTION

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments. Furthermore, words “comprising”, “containing” and “including” should be understood as not limiting the described embodiments to consist of only those features that have been mentioned and such embodiments may contain also features/structures that have not been specifically mentioned.

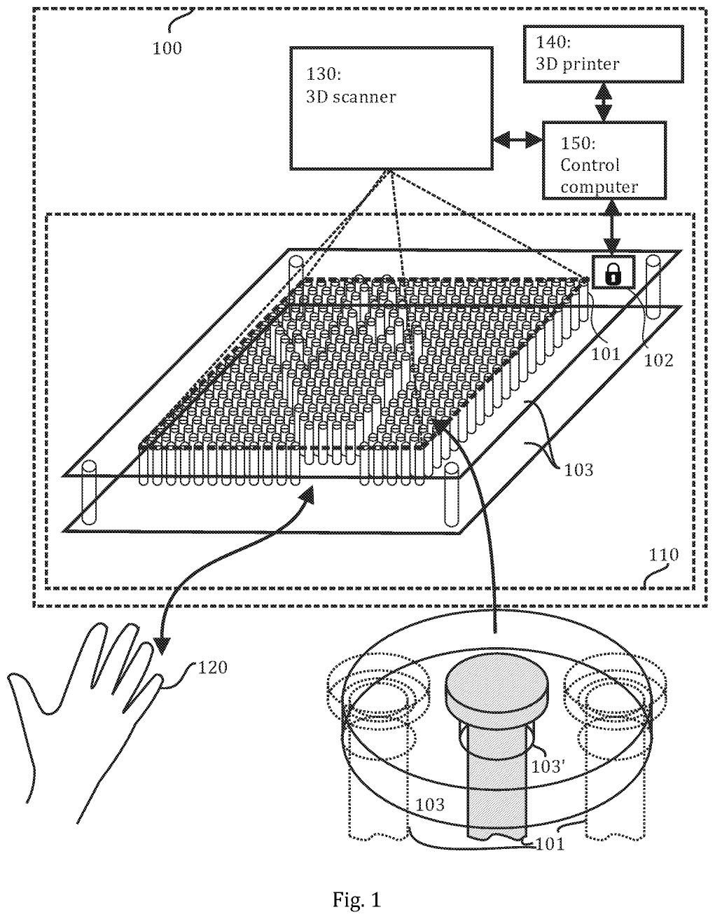

FIG. 1 illustrates an exemplary system according to an embodiment of the invention for 3D scanning as well as 3D printing of an object such as an injured wrist. The illustrated system 100 comprises a pin board tool 110 which in turn comprises at least an array of parallel pins 101 forming the pin board itself and locking means 102 for locking said array of parallel pins in place. The pin board tool 110 may also comprise a fixture 103 or a frame 103 for holding the set of parallel pins. The system may further comprise 3D scanner 130, a 3D printer 140 and a control computer 150 which may be connected to the 3D scanner 130 and the 3D printer 140 as well as the pin board tool 110. In this example, the object to be scanned and the resulting scan of which is to be used in the consequent 3D printing is a human right hand 120.

In some embodiments, the system 100 may not comprise the control computer 150 in which case the use of the 3D scanner 130 and the 3D printer 140 may not be automated. Instead, the 3D scanner 130 and the 3D printer 140 may be operated manually and/or separately by one or more technicians. In some embodiments, each of the 3D scanner 130 and the 3D printer 140 may have their own control computer. The pin board tool 110 may be operated manually or it may be remotely controlled by a control computer which may be the control computer 150. The pin board tool 110, the 3D scanner 130 and the 3D printer 140 may be located within the same device, within the same room or at different places (that is, different rooms or even buildings). In an embodiment, the 3D scanner 130 and the 3D printer 140 are comprised in a single 3D scanning/printing device or system.

The array 101 of parallel pins may be organized on a plane perpendicular to the longitudinal direction of the parallel pins according to a regular mesh, for example, a rectangular mesh as illustrated in FIG. 1. A corresponding set of holes (or perforations) 103′ may be arranged on the fixture 103 allowing the array 101 of parallel pins to penetrate through the fixture 103. The parallel pins in the array 101 may have equal spacing to neighbouring pins in the array 101 and may have equal length. In some embodiments, each parallel pin in the array 101 may be in contact with its neighbouring pins. In such a case, the fixture 103 may not have individual holes for each parallel pin but rather a single large hole (or an opening) for the whole array 101. The array 101 (i.e., the outline of the array) may be of any shape such as rectangular as illustrated in FIG. 1, elliptical or spherical.

Moreover, the parallel pins in the array 101 may be able move freely in their longitudinal direction within a certain movement range but may be fixed in the directions orthogonal to the longitudinal direction. The movement range may be equal to or smaller than the length of the parallel pins. The pins may be metal or plastic cylinders with, for example, circular, elliptical or rectangular cross sections. The other end of each pin (the end facing up in FIG. 1) may have a section with a slightly larger cross section than the cross section of the corresponding hole 103′ in the fixture 103 (only shown in FIG. 1 in the inset for clarity). For example, the pins may be (blunt) nails oriented so that the flattened head of the nail prevents the nail from falling through the corresponding hole 103′ in the fixture 103 as illustrated in the inset of FIG. 1. In some embodiments, said section with the slightly larger cross section may be not be located in either end of the pins but somewhere closer to the middle of the pins.

In some embodiments, top or bottom ends of the parallel pins in the array 101 penetrating through the fixture 103 may be attached to a single elastic layer (not shown in FIG. 1) forming a continuous surface to facilitate the 3D scanning of the object 120 and the 3D printing to be described later. In some cases, a separate elastic layer may be attached to each of top and bottom ends of the parallel pins in the array 101 to form two continuous surfaces, one on top of the array 101 and one under the array 101. In some cases, multiple adjacent elastic layers may be combined to form the continuous surface. The elastic layer may be, for example, a flexible membrane or mesh.

The fixture 103 may comprise two layers (planar structure elements): an upper layer which holds the array 101 of parallel pins and a lower layer which is attached to the upper layer from below by, for example, by bolts or screws, and which provides support for the object 120 to be scanned. To ensure that the parallel pins remain at an upright position at all times (that is, to prevent the parallel pins from tilting), the upper layer may comprise a single relatively thick layer material (as shown in the inset of FIG. 1) or two thinner sublayers of material placed on top of each other, each sublayer comprising a set of holes 103′. In some embodiments, the fixture may comprise only the upper layer. The locking means may be integrated into the fixture 103. For example, in the embodiment where the parallel pins are in contact with the neighbouring pins, the locking means may comprise a single band clamp or more generally one more clamps integrated into the fixture 103 and organized around the array 101 of parallel pins. In an embodiment, the separation between the upper and lower layers may be adjustable for facilitating the scanning of objects of different sizes. While the fixture is rendered as transparent in FIG. 1 for clarity, the fixture may also be partly or fully opaque.

When the locking means 102 are not engaged and no force is asserted to the pins, the ends of all the pins of the array 101 may be aligned in the longitudinal direction. However, when force is asserted to the array 101 in an inhomogeneous manner, for example, when an object 120 (in the illustrated example, a right hand) is pushed against the array 101 from below, some of the pins in the array 101 are forced to protrude to varying degrees from the other side of the array while others remain in their initial positions. The result of this process is a reproduction by the upper ends of the pins in the array 101 of the shape of the object 120 pushed against the array 101 of parallel pins from below.

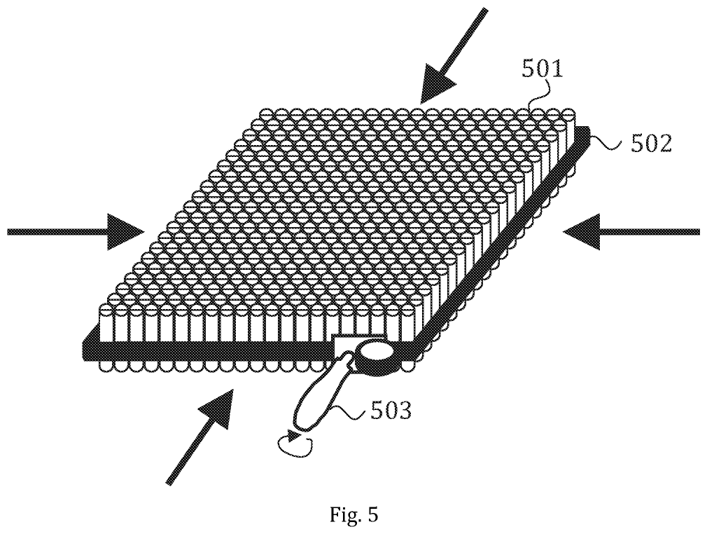

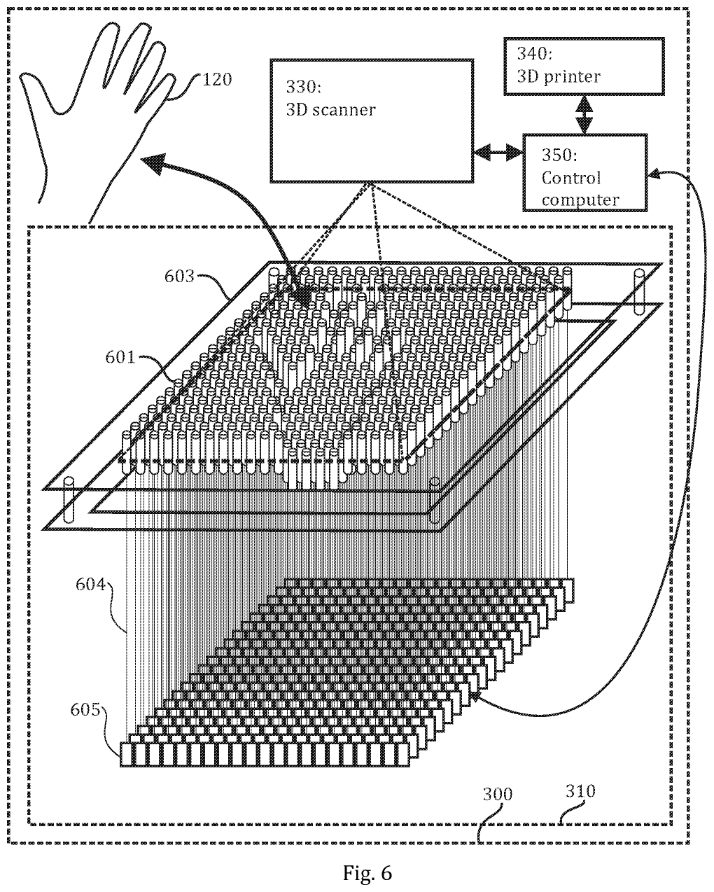

In order to prevent this reproduced shape of the object 120 from disappearing once the object is removed from under the array 101, the locking means 102 may be activated which causes the pins in the array 101 to be locked in place until the lock is again released. The locking means may be realized, for example, as a physical gripping mechanism, for example, a clamp. For example, a shared clamping or gripping mechanism may be organized for fixing the whole array 101 in place simultaneously. The shared clamping or gripping mechanism may be based on a clamp, e.g., a band clamp, or multiple clamps organized around the array 101 of parallel pins which are preferably in contact with each other such that clamping the outer pins with the band clamp causes the inner pins also to become clamped as will be described in detail in relation to FIG. 5. In some embodiments, two or more clamping or gripping mechanisms (e.g., clamps or band clamps) may be organized so that each gripping mechanism is used to lock a certain set of two or more parallel pins in the array 101 (the two or more parallel pins being clamped against each other and/or the fixture). In some embodiments, motors or actuators connected to each parallel pin or some of the parallel pins in the array 101 may be used as locking means as well as for free control of the parallel pins as will be described in detail in relation to FIG. 6. The locking means 102 may be activated manually or automatically the control computer 150, for example, when the control computer detects that an object is placed inside the pin board tool 110.

The shape of the object 120 reproduced by the array 101 of parallel pins (or to be precise, reproduced by the protruding ends of the parallel pins in the array 101) and locked in place by the locking means 102 may be scanned in three dimensions by the 3D scanner 130 to produce a 3D model of the shape. If flexible membrane is attached to one side of pin bed, the 3D scanner may alternatively scan the 3D surface reproduced in this flexible membrane. Obviously, the 3D model corresponds only to one side of the object (that is, the side pressed against the array of parallel pins). The 3D scanner may employ any current or future, contact (probing by physical touch) or non-contact (probing by radiation) 3D scanner technology. For example, the 3D scanner 130 may be a coordinate measuring machine (CMM) or a time-of-flight 3D laser scanner.

The 3D scanner 130 may, first, generate a 3D point cloud based on the measurements performed by the 3D scanner 130. The 3D point cloud may comprise x, y and z coordinate values corresponding to a plurality of points on the surface of the array 101 of parallel pins. The resulting 3D point cloud and any other results produced by the 3D scanner 130 may be output to the control computer 150. Thereafter, the 3D scanner 130 or the control computer 150 may extrapolate the shape of the object based on the points in the 3D point cloud creating a 3D model of the scanned surface. Thereafter, the scanned surface may be transferred to a 3D printing software, which understands this surface as a 3D print bed on which the 3D object being reproduced is 3D printed.

In an embodiment of the invention, the scanning of the locked array 101 of parallel pins may be conducted separately from the capturing of the shape of the object 120 by locking the array 101, in a separate location. Moreover, the scanning may be equivalently conducted for either side of the array 101 of the parallel pins as both sides contain the same information on the shape of the object 120. The array 101 along with a part of the fixture 103 (e.g., the upper layer of the fixture 103) may be removable from the rest of the setup so that it may be easily moved to another location where a 3D scanner is available.

After the 3D model of the shape of the object 120 has been generated by the 3D scanner 130 and/or the control computer 150, a three-dimensional object based on said 3D model may be printed by the 3D printer 140. The 3D printer 140 may be a 3D printer employing any current or future 3D printing technology. For example, the 3D printer may use fused filament fabrication (FFF), where the 3D printed object 201 is produced by extruding small beads or streams of material which harden immediately to form layers. The 3D printer 140 may have multiple nozzles having possibly different dimensions which may be used for printing different materials. The material or materials used for printing may comprise, for example, polymers such as thermoplastics, metals, metal alloys, plaster and rubbers. To give another example, a laser sintering technique such as direct metal laser sintering (DMLS), selective laser sintering (SLS) or selective laser melting (SLM) may be used for 3D printing in some embodiments. In laser sintering, a high-power laser is used to fuse (“sinter”) metal powder into a solid part by melting it locally. The 3D printed object is built up in this way additively layer by layer.

In some embodiments, the material used for 3D printing may be photos curable, that is, the material may be hardened as a result of interaction with electromagnetic radiation in the visible or near-visible range, e.g., ultraviolet range. In other embodiments, similar hardening of the material may be achieved via one or more chemical reactions. The aforementioned techniques have the benefit that the corresponding nuzzle of the 3D printer does not have to be heated before printing.

As only one side of the object 120 is captured in the embodiment illustrated in FIG. 1, the three-dimensional printed object does not fully correspond to the scanned object 120 but comprises a single surface corresponding to the scanned surface of the object 120. For example, the 3D printed object may be a relatively thin but sturdy (i.e., form-keeping) three-dimensional layer of material having a certain thickness and following the shape of the scanned surface of the object 120. In other embodiments, the 3D printed object may be a more bulky piece of material one side of which corresponds to the scanned surface of the object 120.

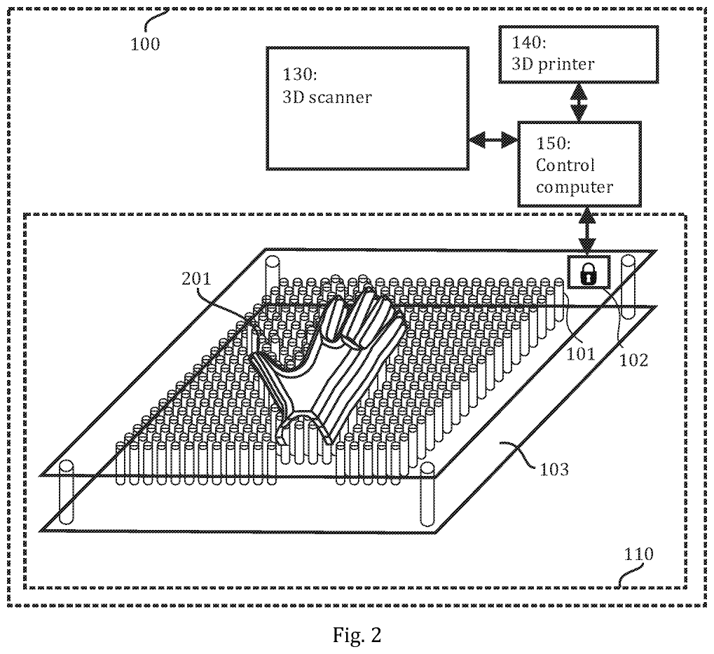

The 3D printing may be conducted directly on top of the array 101 of parallel pins which is still locked in place by the locking means 102 in the same position as during the 3D scanning. In other words, the array 101 of parallel pins (or the elastic material layer connected to the ends of the parallel pins of the array 101) may act as a print bed on which the 3D printer 140 adds material. In the embodiment where the 3D scanner 130 and the 3D printer 140 are comprised in a single 3D scanning/printing device or system, the whole pin board tool 110 may remain in the same position throughout the 3D scanning and printing procedures. FIG. 2 illustrates the 3D scanning/printing system of FIG. 1 after the 3D printing showing the 3D printed object 201 3D printed on top of the array 101 of parallel pins. It should be appreciated that the layers visible in the 3D printed object 201 in FIG. 2 are purely illustrative and are not meant to reflect the composition or quality of the 3D printed object or the method of 3D printing used. By using the array 101 of parallel pins as a print bed for 3D printing, no additional support for the 3D printed object 201 is needed during the 3D printing process as the surface of the array 101 of parallel pins follows the surface of the 3D printed object. Conventionally, the support structures for a given object to be 3D printed need to be prepared beforehand and/or are printed simultaneously with the actual 3D printed object using special support material. The support material may stick to the 3D printed object meaning that considerable work (e.g., sanding of the support material or dissolving the support material chemically) may be required to remove the support material from the 3D printed object in a clean manner. Despite of this additional work, the use of support materials may still result in blemishes or surface roughness. Finally, the need for support materials for the support structures may also increase the total cost of the 3D printing.

Considering the application of 3D printed casts for facilitating healing of fractures, the aforementioned form-fitting thin layer of material may provide perfect support for the fractured area (that is, the area that was 3D-scanned) while still being potentially relatively light-weight compared to conventional casts made from plaster. To make the 3D printed cast even lighter, the 3D printed object may have a nested or perforated structure. Perforated or nested 3D printed casts have other advantages in addition to the lightness such as providing aeration to the skin under the cast improving the health of the skin as well as providing a way for the patient to scratch the skin under the cast in the case of itching caused by the cast. The 3D printed object 201 may be fastened around the body part where the fracture is located, for example, using gauze. The 3D printed object 201 may be modified, for example, some parts which are not necessary for supporting the fractured area may be removed, before it is used for the creating the cast. A fully 3D printed cast enclosing the whole body part (most likely a limb) may be prepared based on two 3D scans as will described in relation to a later embodiment of the invention.

In some embodiments, the object 201 may 3D printed using multiple different materials some of which may be fibre-based materials. For example, the object 201 may be 3D printed by using only a single filament, which is composed of continuous fibre reinforcement and thermoplastic matrix polymer. The fibre reinforcement may be also in form of non-impregnated fibre strand, which is in-nozzle impregnated using photo or heat curable polymer.

In an embodiment of the invention, the following print materials may be used for the polymer and the continuous fibre reinforcement:
Polymer (polymer wire) may be in form of continuous 0.1-5 mm diameter filament. The inner diameter of polymer nozzle as well as the printed line width may be fine (both preferably 0.1-1.8 mm).
Fibre reinforcement may be in form of relatively thick filament (0.1-10 mm). Thus, the fibre nozzle inner diameter may be 0.1-20 mm and printed line width may be 0.2-40 mm.
   The fibre reinforcement in the parts printed by utilizing the 3D printer may have thicker layer thickness than that the layer thickness of polymer layers. Thus, there may be several polymer layers on the same height which only one fibre layer covers. The fibre layers may be embedded in the interior of the parts being printed. As the majority of printing time is typically consumed by filling the parts being printed, the increase of layer thickness in the interior of parts may decrease the printing time.

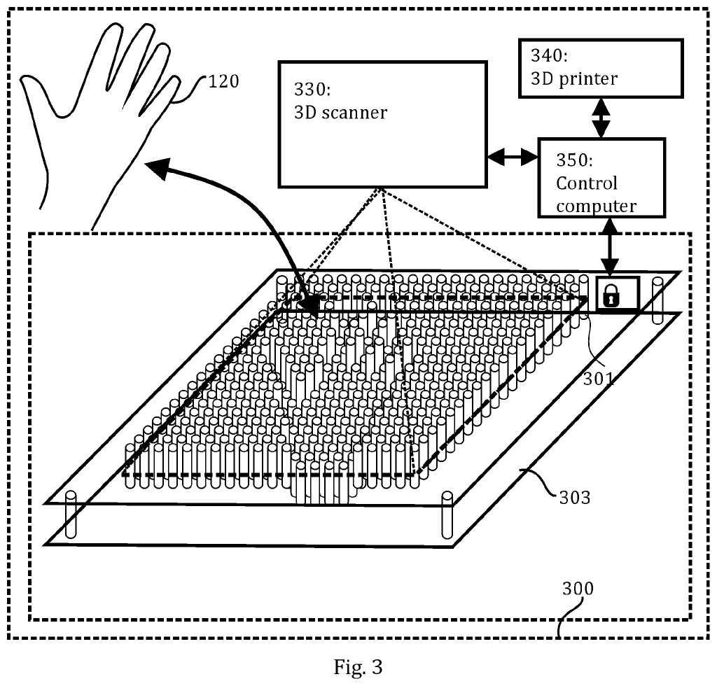

FIG. 3 shows an alternative 3D scanning/printing system 300 corresponding to an embodiment of the invention. The illustrated alternative system 300 corresponds for the most part to the system illustrated in FIGS. 1 and 2. The elements 330, 340, 350 may correspond to elements 130, 140, 150 of FIGS. 1 and 2. The difference between the two systems lies in the orientation of the object 120 to be scanned in relation to the array of parallel pins during the 3D scanning and in the way the array 301 of parallel pins is attached to the fixture 303. During the scanning the object 120 is placed on top of the array 301 of parallel pins. The parallel pins in the array 301 may protrude from the fixture 303 when no object is placed on the pins and may be pushed down by the object 120 to be scanned. The parallel pins in the array 301 may be attached to the fixture 303 in such a way that that gravity alone is not enough to pull them down through the corresponding holes in the fixture 303, but they may move if a relatively small amount of physical force is exerted on them from above. For example, a plurality of springs may be connected between the parallel pins and the fixture 303 in some embodiments. In other embodiments, one end of each parallel pin may be inserted into a liquid-filled tube. By controlling the level of liquid in the tube, the parallel pins may be locked in place. In other embodiments, each or some of the parallel pins in the array 301 may be connected to actuators or motors as will be described in detail in relation to FIG. 5.

In this embodiment, the pattern formed by the arrays 301 of parallel pins is concave while in the embodiment of FIGS. 1 and 2 it was convex (from the point of view of the user). Nevertheless, the same information on the surface of the scanned object 120 may be contained in both patterns assuming the surface of the object 120 pushed against the surface is the same. This, however, not the case in FIGS. 1 and 2 and FIG. 3.

In the illustrated example of FIG. 3, the shape of the palm side of the hand is captured by the array 301 of parallel pins while in the illustrated example of FIGS. 1 and 2, the shape of the back of the hand (the hardel) is captured by the array 101 of parallel pins. In other words, the two scans of the locked arrays 101, 301 provide different information about the object. This information may be combined to form a full 3D model of the object. Moreover, the two scans may be used to 3D print two parts which when combined (for example, glued together) may form a fully 3D printed cast. Obviously, two separate 3D scans may be conducted with either one of the two systems 100, 300 to get the same result. However, rotating the body part, especially a fractured body part, by 180° for another scan may be difficult and even painful for the patient. Therefore, substantial benefit may be derived from having two separate arrays of parallel pins for scanning different sides of the object.

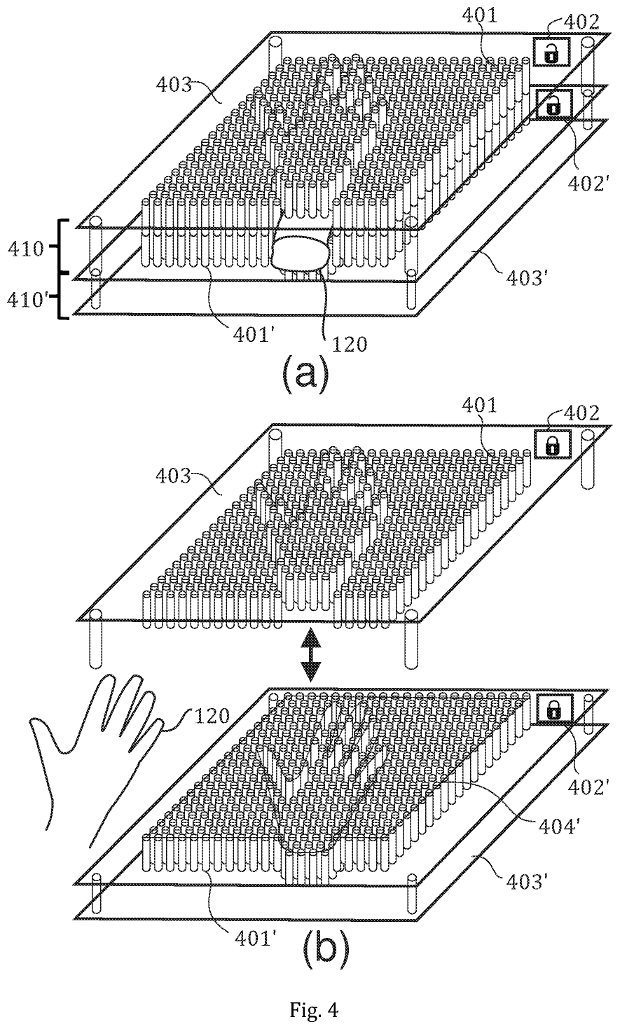

The 3D scanning may be facilitated even further by providing a 3D scanning/printing system which may allow for simultaneous scanning of both sides of the object or to be precise, scanning of two locked arrays of parallel pins corresponding to opposite side of the object. Such an embodiment of the invention illustrated in FIG. 4. Specifically, FIG. 4 illustrates two distinct phases of the 3D scanning procedure. In FIG. 4(a), the object 120 to be scanned is in position for the two locking means 402, 402′ for locking the parallel pins of the two arrays 401, 401′ in place to be activated. The object 120 causes some of the pins of the arrays 401, 401′ to protrude so that the shape of the top and bottom side of the object is reproduced by top and bottom surfaces (patterns) formed by the arrays 401, 401′, respectively. By activating the locking means 402, 402′ these two patterns may be locked in place. In the illustrated position, the insertion of any object between the two arrays of parallel pins may be difficult. Therefore, the two pin board tools 410, 410′ may be easily detachable from each other to facilitate the insertion of the object 120. In an embodiment, one or both of the pin board tools 410, 410′ may be mounted on a movable stage or platform to facilitate the operation of the system. In FIG. 4(b), the two locking means 402, 402′ have been activated, the object 120 has been removed from between the two pin board tools 410, 410′ and the two pin board tools 401, 402, 403, 401′, 402′, 403′, 404′ have been pulled apart. As illustrated in FIG. 4(b), the top and bottom surfaces of the object 120 have been captured by the top and bottom pin board tools 410, 410′, respectively. The element 404′ represents an elastic layer attached, in this example, to the top ends of the parallel pins in the bottom array 401′ to facilitate 3D scanning and printing. Though it is not explicitly shown in FIG. 4, a similar elastic layer may also be attached to the bottom (and/or top) ends of the parallel pins in the top array 401.

A 3D scanner, a 3D printer and a control computer as illustrated in FIGS. 1 to 3, though not shown in FIG. 4, may be used also in conjunction with the embodiment of FIG. 4 predominantly in the same way as described in relation to FIGS. 1 to 3. The 3D scanning may be conducted at the same time for the two pin board tools 410, 410′ when the setup is “opened” as shown in FIG. 4(b) or it may be conducted separately for the two pin board tools 410, 410′. The two 3D printed parts may be 3D printed separately using the respective locked pin board tools 410, 410′ as print beds and combined using, for example, an adhesive to produce a fully three-dimensional object (e.g., a cast).

While using two pin board tools arranged on opposite sides of the object as illustrated in FIG. 4 enables capturing the shape of many relatively simple and/or flat objects (e.g., a hand or a wrist of a person) accurately, the shape of an object with more detailed geometry, especially in the sides of the object orthogonal to the two pin board tools, may not be captured as well. To overcome this issue, the concept of capturing a shape of an object using a pin board tool according to previous embodiments may be further generalized by using three or more pin board tools arranged around the object. Specifically, the two or more pin board tools may be arranged such that parallel pins of the two or more pin board tools are parallel to a common plane penetrating the object and facing the object and angular separation between all neighbouring pin board tools of the two or more pin board tools is equal. The angular separation may correspond to angular separation as observed from a centre of the object in the common plane, that is, the geometric centre of the intersection area between the common plane and the object, or some other point in said intersection area. For example, instead of capturing only the top and bottom surfaces of an object using two pin board tools, three, four, five or six pin board tools may be arranged in the described manner around the object with a 120°/90°/72°/60° separation, respectively. The number of the pin board tools necessary to capture the shape of the object with a sufficient accuracy depends on the shape of the object as well as the level of the desired accuracy. Alternatively, a pin board tool may be arranged in three dimensions on each side of the object (i.e., on each side of a cube surrounding the object) to more fully capture the shape of the object. Obviously, such a configuration is not possible if the object to be captured is a limb though five pin board tools may still be used if an extremity of the limb is to be captured (e.g., a foot instead of a knee or an ankle).

As described earlier, one or more clamps may be used as the locking means to lock the array of parallel pins in place for 3D scanning and printing. One exemplary, simplified realization of a band clamp used for clamping an array of parallel pin according to an embodiment of the invention is illustrated in FIG. 5.

Referring to FIG. 5, the array 501 of parallel pins is shown without a fixture for clarity though it should be appreciated that the illustrated clamping structure may be implemented in conjunction with any of the embodiments of the invention discussed earlier. In the illustrated embodiment of the invention, it is required that the distance between neighbouring parallel pins is small enough that a single band 502 when tightened around the array 501 may be used for fixing the whole array 501 in place. In such a case, the fixture may not have individual holes for each parallel pin (as illustrated in the inset of FIG. 1) but rather a single large hole for the whole array, as discussed in relation to FIG. 1.

The illustrated band clamp comprises two parts: a band 502 and a tightening apparatus 503. The band 502 (equally called a belt or a strap) which encloses the array 501 of parallel pins may be made a variety of materials such as metal or webbing. The tightening apparatus 503 may comprise a screw or a ratchet mechanism which, when operated either manually or automatically, causes the circumference of the band 502 enclosing the array 501 to shorten, thus locking the array 501. In the illustrated example, the band 502 may be tightened by simply turning (rotating) a handle or a grip of the tightening apparatus 503. In some embodiments, the tightening apparatus 503 may be connected a control computer according to any of the previous embodiments to enable locking via the control computer.

In some embodiments, one or more support structures (not shown in FIG. 5) may be arranged to hold and guide the band 502 and to facilitate tightening the band 502. For example, such support structures may be organized to each corner of the array 501 having a polygonal shape (e.g., a rectangular shape as in FIG. 5).

In an embodiment of the invention, the operation of the pin board tool(s) may be fully automated. The arrays of parallel pins and the locking means may be automated such that once an object is pushed against the parallel pins, the locking means are activated after a pre-defined amount of time. One or more pin board tools may be mounted to one or more movable platforms the position of which may be controllable physically or by the control computer or other automated means in one or more dimensions. The one or more movable platforms may enable movement at least in the longitudinal direction of the parallel pins in each corresponding pin board tool.

The movement of all separate pins in the array or arrays (or a subset of said pins) may also be fully automated. In some embodiments of the invention, all or some of the parallel pins may be connected to separate actuators or motors which may be used, for example, via the control computer, to control the movement of the individual parallel pins and/or as the locking means. The actuators may be organized directly above or below the parallel pins or they may be farther removed from the parallel pins and connected to them via mechanical linkages. An exemplary embodiment demonstrating this concept is illustrated in FIG. 6. In FIG. 6 which is based on the setup of FIG. 3, each parallel pin in the array 601 is connected via a mechanical linkage 604 to an actuator or motor 605. A hole is arranged in the fixture 603 to allow the mechanical linkages to pass through the fixture 603. In the illustrated example, the actuators or motors 605 may act as locking means as well as allowing for free control of the vertical positions of the parallel pins in the array 601 by the control computer 350. Separate locking means 602 may be arranged in some embodiments, in addition to the actuators or motors 605, to allow for manual operation. The actuators or motors 605 may also act as means for holding the parallel pins upright, in a “pushed up” position and for allowing them to be pushed down in a controlled manner when force is exerted on them.

The embodiments utilizing actuator or motors such as the one illustrated in FIG. 6 have the benefit of enabling the use of previously acquired scan data for creating a print bed pattern for the pin board tool without the need of having the actual object available. For example, the 3D scanning of a fractured wrist could be conducted in one hospital using one or more first pin board tools acting as scan beds while the manufacturing of the 3D cast based on the scanning data using one or more second pin board tools acting as print beds conforming to the surface of the object to be printed could be conducted in another hospital without having to transport the locked pin board tool from one place to another. The print beds may be automatically adjusted based on the scanning data to have the same pattern as the scan beds. In some embodiments, the 3D scanner may be connected (possibly via a terminal device such as a personal computer, a tablet computer or a smart phone) using a communications link to the control computer controlling the 3D printer and the one or more second pin board tools so that the scanning results may be easily shared to facilitate the 3D printing. In some cases, no 3D scan may even be used. Instead, the print bed pattern for the pin board tool may be based on a 3D modelled object.

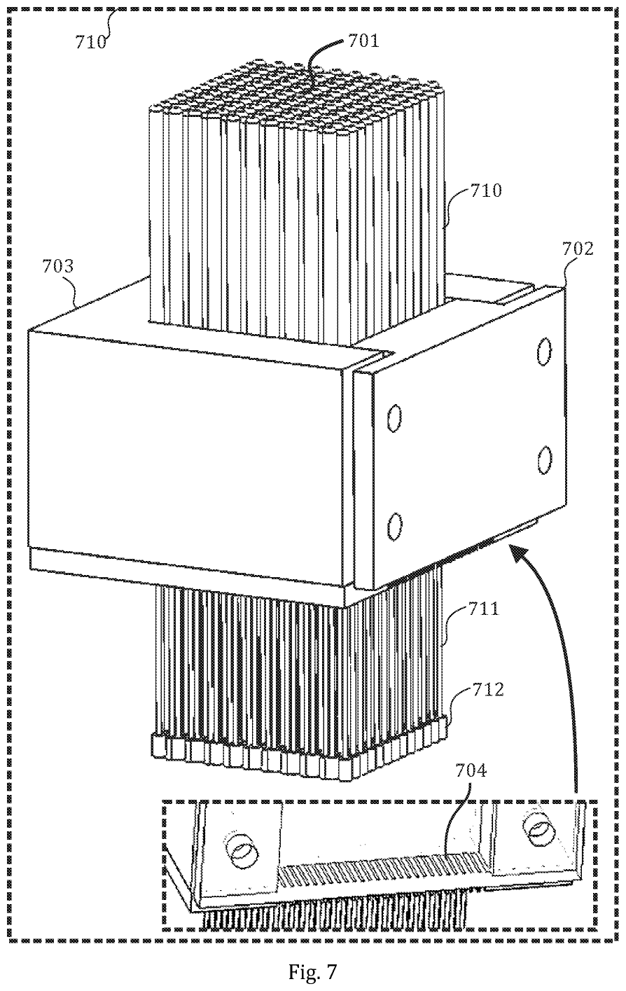

FIG. 7 illustrates a pin board tool according to an alternative embodiment. Said pin board tool may be used in conjunction with any of the exemplary systems of FIGS. 1 to 4 and 6, said pin board tool replacing the pin board tool or tools illustrated in said Figures. Thus, any functionalities of the systems according to earlier embodiments apply also to the following alternative embodiments for realizing the pin board tool.

Referring to FIG. 7, the pin board tool 710 comprises, similar to the earlier embodiments, an array 701 of parallel pins (specifically, a rectangular array in the non-limiting illustrated example) which is held by a fixture, comprising here at least a comb structure 704. However, in contrast to the earlier illustrated embodiments, each of the parallel pins in the array 701 comprises three distinct sections, namely a first end section 710 (the top end section in FIG. 7), a second end section 712 (corresponding to opposite end to the first end section 710, i.e, the bottom end section in FIG. 7) and a middle section 711. All the sections 710, 711, 712 may be cylindrical in shape. The first end section 710 may be considerably longer than the other end section 712 and may act as the section of the pin on or against which the object to be scanned is placed. Furthermore, the middle section 711 may have smaller cross section compared to one or both of the end sections 710, 712 which may have equal or differing cross sections. In the illustrated example, the first and second end sections 710, 712 of the parallel pins have equal cross section which is larger than the cross section of the middle sections 711 of the parallel pins. The cross section of the thin middle section 711 may be sufficiently small so that the parallel pins in the array 701 are able pass between the teeth of a comb structure 704 comprised in the fixture. In the initial position (that is, when no locking mechanism is engaged), the spacing between the end sections 710, 712 of the parallel pins may be relatively small but the pins may not be in contact with each other. In some embodiments, a grid or a mesh structure or a perforated structure (i.e., a plurality of holes in the fixture as discussed in relation to FIG. 1) may be used instead of the comb structure 704 for holding the pins. In other embodiments, the second end section 712 may be omitted.

In the illustrated alternative example, the locking means comprise a clamp formed by a stationary part 703 and a clamping plate 702. The stationary part may be arranged at least along one side of the array 701, namely the side opposite to the side of the clamping plate. The surface of the stationary part 703 facing the array may follow the shape of the corresponding side of the array (i.e., be flat if the array is rectangular or curved if the array is cylindrical/elliptical). As illustrated in FIG. 7, the stationary part may further extend to the other two sides of the rectangular array 701 along which the clamping plate 702 is not arranged to facilitate the clamping. The clamping plate 703 may be arranged against the array 701 of parallel pins, above (or below) the comb structure and orthogonal to the teeth of the comb structure. Moreover, the clamping plate 703 may extend over a width of the array. The clamping plate 703 may be configured to clamp the parallel pins against the stationary part causing at least one of the end sections 710, 712 (in the illustrated example both end sections) of the parallel pins to be pushed tightly against each other and the stationary part locking the parallel pins in place. The clamping plate 703 may be tightened against the stationary part 703, for example, using screws or bolts or any other known tightening/fastening mechanism. Specifically, the screws or bolts may be inserted into holes 706.

In some alternative embodiments, the cross section of the middle sections 711 of the parallel pins may be larger than the cross section of the corresponding first and second end sections 710, 712. In such embodiments, a material sheet (e.g., a metal sheet) with a plurality holes adapted to allow only the first and second end sections 710, 712 to penetrate through it may be arranged above and/or below the comb structure. The material sheet acts to keep the pins inside the pin board tool as the comb structure itself is not able to prevent this, in contrast to the embodiment illustrated in FIG. 7.

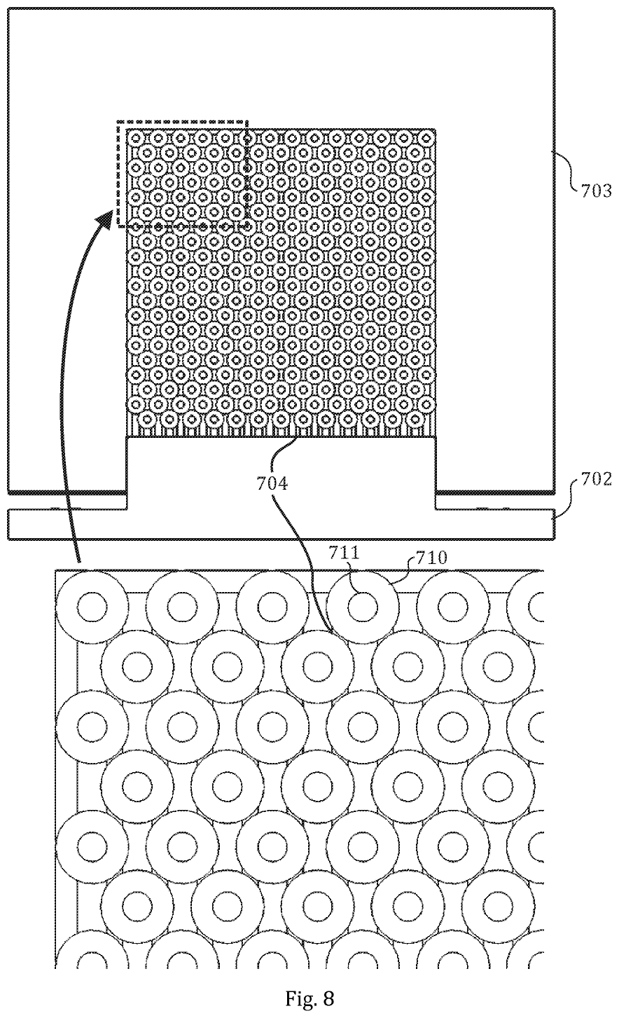

FIG. 8 illustrates the pin board tool of FIG. 7 from above in two different configurations, namely when the locking means are not activated (top) and when the locking means are activated (bottom). In the top part of FIG. 8, the end sections 710, 712 are in contact with each other though the spacing between the end sections is relatively small as may be observed from the top inset of FIG. 8. When the locking means are activated, that is, the clamping plate 702 is tightened against the stationary part and the array 701 of parallel pins, the end sections 710, 712 (or at least one of the end sections 710, 712) are pushed tightly against the stationary part 703 and each other preventing any horizontal as well as vertical movement.

The pin board tool 710 as shown in FIGS. 7 and 8 may be used by turning the pin board tool 710 upside down in view of the orientation of FIG. 7 in which case the parallel pins move to a first extreme position, being held by the second end sections 712 not being able to fit through the teeth of the comb structure 704 (the alignment of FIG. 7 corresponding to a second extreme position where the first end section 710 is in contact with the comb structure 704). The object to be scanned may be pushed against the array of parallel pins from below causing the parallel pins to align with the surface of said object. The locking means may, then, be activated by tightening the clamping plate 702 against the parallel pins in the array 701 and the stationary part 703.

Obviously, the operation as described in the previous paragraph works only if the pin board tool 710 is oriented in the aforementioned way (i.e., upside down compared to FIG. 7) and the object is inserted from below. If it is preferable that the object may be placed on the pin board tool keeping the orientation of the pin board tool as depicted in FIG. 7, an additional element is needed for realizing said functionality. In some embodiments, a spring for each parallel pin may be placed in one of two places to provide support for said parallel pin, that is, to prevent the parallel pins from being pushed fully down by gravity when no object is placed on the pin board tool 710. First alternative is to place a spring between the comb structure 704 (or a grid or perforated structure) and the first end section 710 of each parallel pin. The spring may be placed next to the middle section 711 of the parallel pin or the spring may coil around the middle section 711 of the parallel pin. Second alternative is to place a spring under the second end section 712 of each parallel pin. Obviously, in such embodiments the fixture should comprise a support structure (e.g., a plate) under pin board tool as depicted, for example, in FIG. 3. In some embodiments, the set of springs placed under the pin board tool may be replaced by a continuous piece or multiple continuous pieces of elastic material.

In some embodiments, multiple clamping plates may be used. For example, two clamping plates may be placed on opposite sides of the array 701 of parallel pins so that the clamping plates are configured to clamp against each other (and against the array 701 of parallel pins). In other embodiments, two L-shaped clamps in two corners of the array or four L-shaped clamps in four corners of the array may be used. In such embodiments, each L-shaped clamp may be configured to clamp in a diagonal direction of the rectangle formed by the array.

In some embodiments, the array 701 of parallel pins may be surrounded by an elastic layer to facilitate the clamping (i.e., the locking) so that the clamping plate 702 is clamping the array 701 of parallel pins through the elastic layer. In other words, the elastic layer may be arranged between the array 701 of parallel pins and the stationary part 703 and the clamping plate 702.

FIG. 8 illustrates the pin board tool of FIG. 7 from above in two different configurations, namely when the locking means are not activated (top) and when the locking means are activated (bottom). In the top part of FIG. 8, the end sections 710, 712 are in contact with each other though the spacing between the end sections is relatively small as may be observed from the top inset of FIG. 8. When the locking means are activated, that is, the clamping plate is tightened against the stationary part and the array 701 of parallel pins, the end sections 710, 712 pushed tightly against the stationary part 703 and each other preventing any horizontal as well as vertical movement.

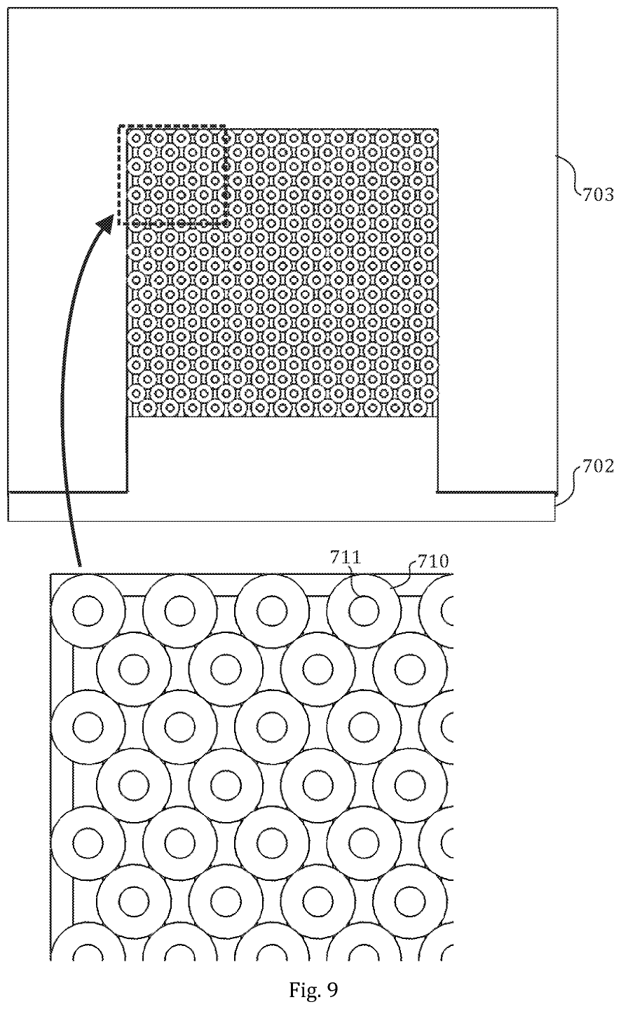

FIG. 10 illustrates another pin board tool according to an alternative embodiment. Said pin board tool may be used in conjunction with any of the exemplary systems of FIGS. 1 to 4 and 6, said pin board tool replacing the pin board tool or tools illustrated in said Figures. Thus, any functionalities of the systems according to earlier embodiments apply also to the following alternative embodiment for realizing the pin board tool.

Referring to FIG. 10, the illustrated pin board tool is in many aspects similar to the pin board tool of FIGS. 7 to 9. Namely, the comb structure 1004 (not visible in FIG. 10), the locking means (comprising elements 1002, 1003) and the first end section 1010 and the middle section 1011 of the parallel pins may be similar to the comb structure 704, the locking means (comprising elements 702, 703) and the first end section 710 and the middle section 711 of the parallel pins in FIG. 7. However, instead of the second end section 1012 being a short and broad cylindrical part as in FIG. 7, the second end section 1012 in FIG. 10 comprises a tapering of the cross section of the cylinder from a first cross section next to the middle section 1011 to a considerably smaller second cross section at the end of the second end section 1012, thus forming a needle-like structure. The first cross section of the second end section 1012 may be larger than the cross section of the middle section 1011 as illustrated in FIG. 10 or equal to or even smaller than the cross section of the middle section 1011. In these embodiment, the parallel pins in the array 1001 may be held up, not by springs as described earlier with other embodiments, but with a piece of soft porous material 1030 (e.g., a sponge) through which the needle-like second end sections 1012 of the parallel pins may penetrate. The extent of how much the parallel pins penetrate the piece of porous material 1030 depends on the force applied to the parallel pins of the array 1001. Thus, the piece of porous material 1030 may act as a rudimentary, secondary locking mechanism for the parallel pins. The final locking of the parallel pins may still be achieved as discussed with earlier embodiments. In some embodiments, a piece of soft porous material 1030 may be arranged as discussed above in conjunction with an array of a parallel pins according earlier embodiments (i.e., without a needle-like taper). In other embodiments, element 1030 may correspond to a piece of elastic material or an array (or a set) of springs, instead of a piece of soft porous material, as discussed earlier.

In some embodiments, a piece of soft porous material may be used in an alternative way which does not necessitate the use of tapered pins. In a pin board tool according an embodiments as illustrated in FIGS. 7 to 9, a piece of porous material may be placed between the comb structure and the first end section of the parallel pins (i.e., above the comb structure in the configuration of FIG. 7). The piece of porous material may penetrate through the middle sections of the parallel pins. To be precise, the piece of porous materials may penetrate longitudinally only a part of the middle sections, the extend of said penetration depending on the force applied to the pins and thus how large a portion of the middle section is “above” the comb structure. As the first sections of the parallel pins are pushed down, the piece of porous material 1130 is able to contract enabling the movement of parallel pins in a controlled manner due to the resistance caused by the piece of porous material 1130. Also in this embodiment, the final locking of the parallel pins may still be achieved as discussed with earlier embodiments with locking means.

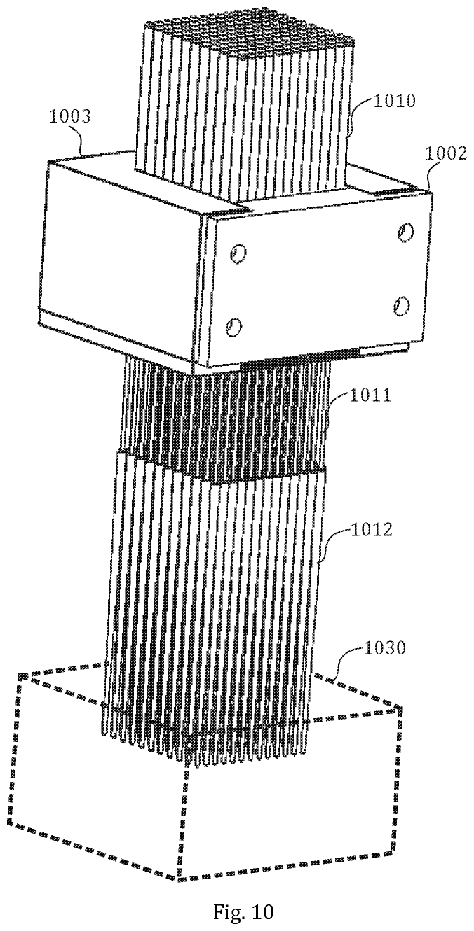

FIG. 11 illustrates a process for capturing a surface of an object using the pin board tool, scanning a pattern formed by the pin board tool and 3D printing an object based on the scanning results using the pin board tool as a print bed. The illustrated process may be carried out by the 3D printing/scanning system illustrated in any of FIGS. 1 to 4 and 6 or a combination thereof or by the control computer of said Figures, possibly utilizing one or more elements from any of FIGS. 5 and 7 to 11. The control computer may be connected to and able to control a 3D scanner, a 3D printer and/or locking means of a pin board tool. Moreover, the control computer may be able to at least sense and possibly also control the position of the parallel pins in the pin board tool.

Referring to FIG. 11, it is provided, in block 1101, a first pin board tool comprising a first array of parallel pins which may be of equal length, a fixture holding the first array of parallel pins and first locking means for locking the first array of parallel pins in place, wherein the array of parallel pins are aligned in the longitudinal direction when the first pin board tool is empty, the first pin board tool being configured such that the parallel pins in the first array are able to move freely in a longitudinal direction of the parallel pins independent of each other within a first movement range when the first locking means are inactive. The first movement range may be equal to or smaller than a length of the parallel pins in the first array. The pin board tool may be as described in relation to any of FIGS. 1 to 5. Then, the control computer detects, in block 1102, an object being placed against the first array causing one or more parallel pins in the first array of parallel pins to protrude. In response to the detecting, the control computer causes, in block 1103, locking, using the first locking means, the first array of parallel pins in place. The locking means may be activated only after a pre-defined time has been passed from the detecting. In response to the locking using the first locking means, the control computer causes, in block 1104, 3D scanning a first pattern formed by the first array of parallel pins comprising the one or more protruding parallel pins in the first array. Finally, the control computer causes, in block 1105, 3D printing using one or more printing materials a first printed object based on the first scanned pattern using the locked first pin board tool as a first print bed, wherein a first surface of the first printed object corresponds to the first pattern. The first printed object may comprise a first thin layer of the one or more printing materials following the first pattern and having a nested, perforated or solid structure. The first printed object may be a part for an orthopaedic cast.

In some embodiments of the invention, one or more of the method steps of FIG. 11 may be performed or initiated manually, that is, the step is performed upon an input by a user, while the rest of the method step may still be performed automatically. For example, the locking means may be activated manually by the user when the object is in place and the scanning may be performed upon an input by the user after the locked pin board tool is moved to an appropriate position, for example, inside a 3D printer-scanner system. The step of detecting (block 1102) may be omitted in some embodiments, for example, if the locking means are activated manually by the user. In other embodiments, said step may comprise detecting, by the control computer, a user input indicating that the object is in place and the locking means are activated or a user input indicating that the object is in place after which the locking is performed automatically.

In some embodiments, the first locking means may comprise a plurality of motors or actuators, each motor or actuator being connected to at least one parallel pin in the first array to allow controlling movement, position and locking of said at least one parallel pin as described earlier in relation to FIG. 6. The movement of each parallel pin may be controllable using a separate actuator or motor so that the locking the first array of parallel pins in block 1103 is performed in response to method further comprising moving each parallel pin of the first array of parallel pins using the plurality of actuators or motors or actuators to a position defined by a pre-defined pattern. The pre-defined pattern may have been deters mined based on a previous 3D scan of the object or based on a 3D model of the object.

In some embodiments, a second pin board tool may be provided. Said second pin board tool may be similar to the first pin board tool and may be a part of the same 3D scanning and printing system as the first pin board tool. Further, it may be positioned opposite the first array of parallel pins such that the parallel pins in the second array are parallel to the parallel pins in the first array, as illustrated in FIG. 4. The procedure for the 3D scanning and printing using the second pin board tool may be similar to the one depicted in FIG. 11 for the first pin board tool. The 3D scanning and the 3D printing may be performed simultaneously using the first and the second pin board tools or one after another.

The 3D scanning and printing system may also comprise one or more movable platforms the position of which may be controllable physically or by the control computer as described above. One or more pin board of the first and second pin board tools may be mounted on said one or more movable platforms. In this case, the illustrated method may further comprise raising or lowering one or more pin board tools of the first pin board tool and the second pin board tool such that the object is enclosed by the first pin board tool and the second pin board tool causing the detecting the object being placed against the first pin board tool in block 1102 and the detecting the object being placed against the second pin board tool.

While in FIGS. 1 to 5 the object to be scanned is a hand, it should appreciated that the embodiments of the invention may be used to 3D scan any shape, i.e., a variety of different human or animal body parts and/or non-human objects and 3D print objects based on the scanning using the locked pin board tool as a print bed. Moreover, it should be appreciated that printing three-dimensional casts to support healing of fractures is only one example of an application where the systems according to the embodiments of the invention may be used. The described concept and system may be used to facilitate 3D printing of a plethora of different objects both within the medical field and in other fields. Moreover, it should be appreciated that the embodiments of the invention may be used also independently without whole process cascade, or as parts of different process cascades.

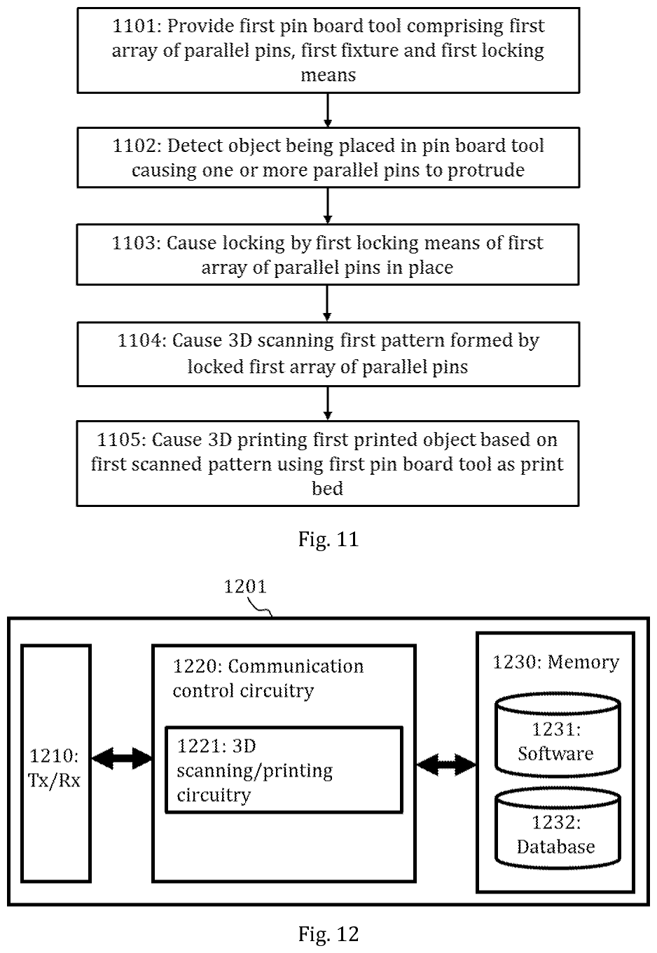

FIG. 12 illustrates an exemplary apparatus 1201 configured to carry out the functions described above in connection with the control computer. The apparatus may correspond to element 150 of FIG. 1 and/or element 350 of FIG. 3 and/or FIG. 6. The apparatus may be an electronic device comprising electronic circuitries. The apparatus may be a separate network entity or a plurality of separate entities. The apparatus may comprise a communication control circuitry 1210 such as at least one processor, and at least one memory 1230 including a computer program code (software) 1231 wherein the at least one memory and the computer program code (software) are configured, with the at least one processor, to cause the apparatus to carry out any one of the embodiments of the control computer described above.

The memory 1230 may be implemented using any suitable data storage technology, such as semiconductor based memory devices, flash memory, magnetic memory devices and systems, optical memory devices and systems, fixed memory and removable memory. The memory may comprise at least one database 1232. The memory 1230 may be connected to the communication control circuitry 1220 via an interface.

The communication interface (Tx/Rx) 1210 may comprise hardware and/or software for realizing communication connectivity according to one or more communication protocols. The communication interface may provide the apparatus with communication capabilities to communicate with and/or control one or more of a 3D scanner, a 3D printer, locking means of one or more pin board tools, parallel pins of one or more pin board tools (e.g., via a plurality of motors or actuators) and one or more movable platforms, for example. The communication interface 1210 may comprise standard well-known components such as an amplifier, filter, frequency-converter, (de)modulator, and encoder/decoder circuitries and one or more antennas.

Referring to FIG. 12, the communication control circuitry 1220 may comprise 3D scanning/printing circuitry 1221 configured to provide control via the communication interface 1210 of one or more of a 3D scanner, a 3D printer, locking means of one or more pin board tools, parallel pins of one or more pin board tools (e.g., via a plurality of motors or actuators) and one or more movable platforms. The 3D scanning/printing circuitry 1221 may be configured to carry out at least some of the steps of FIG. 11.

As used in this application, the term ‘circuitry’ refers to all of the following: (a) hardware-only circuit implementations, such as implementations in only analog and/or digital circuitry, and (b) combinations of circuits and software (and/or firmware), such as (as applicable): (i) a combination of processor(s) or (ii) portions of processor(s)/software including digital signal processor(s), software, and memory(ies) that work together to cause an apparatus to perform various functions, and (c) circuits, such as a microprocessor(s) or a portion of a microprocessor(s), that require software or firmware for operation, even if the software or firmware is not physically present. This definition of ‘circuitry’ applies to all uses of this term in this application. As a further example, as used in this application, the term ‘circuitry’ would also cover an implementation of merely a processor (or multiple processors) or a portion of a processor and its (or their) accompanying software and/or firmware.

In an embodiment, at least some of the processes described in connection with FIG. 11 may be carried out by an apparatus comprising corresponding means for carrying out at least some of the described processes. Some example means for carrying out the processes may include at least one of the following: detector, processor (including dual-core and multiple-core processors), digital signal processor, controller, receiver, transmitter, encoder, decoder, memory, RAM, ROM, software, firmware, display, user interface, display circuitry, user interface circuitry, user interface software, display software, circuit, antenna, antenna circuitry, and circuitry. In an embodiment, the at least one processor, the memory, and the computer program code form processing means or comprises one or more computer program code portions for carrying out one or more operations according to the embodiments of FIG. 11 or operations thereof.

The techniques and methods described in relation to the control computer may be implemented by various means. For example, these techniques may be implemented in hardware (one or more devices), firmware (one or more devices), software (one or more modules), or combinations thereof. For a hardware implementation, the apparatus(es) of embodiments may be implemented within one or more application-specific integrated circuits (ASICs), digital signal processors (DSPs), digital signal processing devices (DSPDs), programmable logic devices (PLDs), field programmable gate arrays (FPGAs), processors, controllers, microcontrollers, microprocessors, other electronic units designed to perform the functions described herein, or a combination thereof. For firmware or software, the implementation can be carried out through modules of at least one chipset (procedures, functions, and so on) that perform the functions described herein. The software codes may be stored in a memory unit and executed by processors. The memory unit may be implemented within the processor or externally to the processor. In the latter case, it can be communicatively coupled to the processor via various means, as is known in the art. Additionally, the components of the systems (e.g., 3D scanning and printing systems) described herein may be rearranged and/or complemented by additional components in order to facilitate the achievements of the various aspects, etc., described with regard thereto, and they are not limited to the precise configurations set forth in the given figures, as will be appreciated by one skilled in the art.

Embodiments as described in relation to the control computer may also be carried out in the form of a computer process defined by a computer program or portions thereof. Embodiments of the method described in connection with FIG. 11 may be carried out by executing at least one portion of a computer program comprising corresponding instructions. The computer program may be in source code form, object code form, or in some intermediate form, and it may be stored in some sort of carrier, which may be any entity or device capable of carrying the program. For example, the computer program may be stored on a computer program distribution medium readable by a computer or a processor. The computer program medium may be, for example but not limited to, a record medium, computer memory, read-only memory, electrical carrier signal, telecommunications signal, and software distribution package, for example. The computer program medium may be a non-transitory medium. Coding of software for carrying out the embodiments as shown and described is well within the scope of a person of ordinary skill in the art.

Even though the invention has been described above with reference to examples according to the accompanying drawings, it is clear that the invention is not restricted thereto but can be modified in several ways within the scope of the appended claims. Therefore, all words and expressions should be interpreted broadly and they are intended to illustrate, not to restrict, the embodiment. It will be obvious to a person skilled in the art that, as technology advances, the inventive concept can be implemented in various ways. Further, it is clear to a person skilled in the art that the described embodiments may, but are not required to, be combined with other embodiments in various ways.

1-24. (canceled)

25. A pin board tool for facilitating three-dimensional, 3D, scanning and printing, comprising:
an array of parallel pins, wherein the parallel pins in the array are aligned in the longitudinal direction of the parallel pins when the pin board tool is empty and each parallel pin comprises a first end section having a first cross section, a second end section having a second cross section and a middle section having a third cross section between the first end section and the second end section, the third cross section being smaller than at least one of the first cross section and the second cross section;
a fixture holding the array of parallel pins, wherein the fixture comprises a comb structure having a plurality of teeth, the middle section being able to pass between the plurality of teeth of the comb structure and at least one of the first end section and the second end section being unable to pass between the plurality of teeth of the comb structure; and
locking means configured to lock the array of parallel pins in place when activated to provide a print bed for 3D printing an object having a surface corresponding to a pattern formed by the array of parallel pins locked in place, wherein the parallel pins in the array are configured to be able to move freely in a longitudinal direction of the parallel pins independent of each other within a movement range when the locking means are inactive and an object is pushed against the parallel pins, the movement range being equal to or smaller than a length of each parallel pin, the locking means comprising a stationary part and a clamping plate, the stationary part being arranged on opposite side of the array relative to the clamping plate and the clamping plate being arranged against at least one of the first end sections and the second end sections of the parallel pins, orthogonal to the plurality of teeth of the comb structure, the clamping plate extending over a width of the array and being configured to clamp the parallel pins against the stationary part causing said at least one of the first end sections and the second end sections of the parallel pins to be pushed tightly against each other and the stationary part locking the parallel pins in place.

26. A pin board tool according to claim 25, further comprising:
one or more layers of elastic material attached to one or more ends of the parallel pins in the array forming at least one continuous surface.

27. A pin board tool according to claim 25, wherein the locking means comprise one or more clamps, each clamp being arranged around two or more parallel pins to be clamped.

28. A pin board tool according to claim 25, wherein the locking means comprise a plurality of motors or actuators, each motor or actuator being connected to at least one parallel pin in the array to allow controlling movement, position and the locking of said at least one parallel pin.

29. A pin board tool according to claim 25, wherein the longitudinal direction of the parallel pins corresponds to a vertical direction and for each parallel pin, the first end section corresponds to a top end section and the second end section corresponds to a bottom end section, the fixture comprising a support structure for the array arranged under the pin board tool, the pin board tool further comprising one of the following to prevent the parallel pins from being pushed fully down by gravity when no object is placed on the pin board tool from above:
a plurality of springs, each spring being attached between the support structure and a second end section of a parallel pin in the array or if the third cross section is smaller than the first cross section, between the comb structure and the first end section;
a piece of elastic material arranged between the support structure and the array of parallel pins or if the third cross section is smaller than the first cross section, between the comb structure and the first end sections of the parallel pins in the array; and
a piece of soft porous material arranged between the support structure and the array of parallel pins or if the third cross section is smaller than the first cross section, between the comb structure and the first end sections of the parallel pins in the array.

30. A 3D scanning and printing system, comprising:
one or more pin board tools according to claim 25;
a 3D scanner configured to scan patterns formed by arrays of parallel pins of the one or more pin board tools locked in place by locking means of the one or more pin board tools; and
a 3D printer configured to 3D print printed objects using one or more printing materials, each of the printed objects having a surface corresponding to a pattern formed by an array of parallel pins locked in place comprised in the one or more pin board tools based on a scanned pattern or a pre-defined pattern using the array of parallel pins locked in place as a print bed.

31. A 3D scanning and printing system of claim 30 wherein the one or more pin board tools comprise two or more pin board tools arranged around the object such that parallel pins of the two or more pin board tools are parallel to a common plane penetrating the object and are facing the object and angular separation between all adjacent pin board tools of the two or more pin board tools is equal, the angular separation being observed from a centre of the object in the common plane.

32. A 3D scanning and printing system of claim 30, wherein the one or more pin board tools consist of two pin board tools arranged on opposite sides of the object so that parallel pins of the two pin board tools are parallel to each other.

33. A 3D scanning and printing system according to claim 30, wherein the one or more printing materials used for 3D printing by the 3D printer comprise a filament composed of continuous fibre reinforcement and thermoplastic matrix polymer.

34. A 3D scanning and printing system according to claim 30, further comprising: a control computer connected to and configured to control one or more of the following: one or more arrays of parallel pins of the one or more pin board tools, one or more locking means of the one or more pin board tools, the 3D scanner and the 3D printer.

35. A 3D scanning and printing system of claim 34, further comprising:
one or more movable platforms on which at least one pin board tool is mounted to provide movement at least in a longitudinal direction of the parallel pins in each corresponding pin board tool, wherein the one or more movable platforms are movable manually and/or the control computer is connected to and configured to control the one or more movable platforms.

36. A method for three-dimensional, 3D, scanning and printing, comprising:
providing a first pin board tool, the first pin board tool being a pin board tool of claim 25;
upon detecting an object being placed against a first array of parallel pins of the first pin board tool causing one or more parallel pins in the first array of parallel pins to protrude, causing locking, using first locking means of the first pin board tool, the first array of parallel pins in place to a first locking position;
causing 3D scanning a first pattern formed by the first array of parallel pins locked to the first locking position comprising the one or more protruding parallel pins; and
causing 3D printing using one or more printing materials a first printed object based on the first scanned pattern using the first pin board tool locked to the first locking position as a first print bed, wherein a first surface of the first printed object corresponds to the first pattern.

37. A method according to claim 36, wherein the first printed object comprises a first thin layer following the first pattern and having a nested, perforated or solid structure.

38. A method according to claim 36, wherein the first locking means comprise a plurality of motors or actuators, each motor or actuator being connected to at least one parallel pin in the first array to allow controlling movement, position and locking of said at least one parallel pin, wherein the locking the first array of parallel pins is performed in response to moving, using the plurality of motors or actuators, each parallel pin of the first array of parallel pins to a position defined by the first pattern determined based on a previous 3D scan of the object or a 3D model of the object.

39. A method according to claim 36, further comprising
providing a second pin board tool comprising a second array of parallel pins positioned opposite the first array of parallel pins such that the parallel pins in the second array are parallel to the parallel pins in the first array, a second fixture holding the second array of parallel pins and second locking means for locking the second array of parallel pins in place, wherein the second array of parallel pins are aligned in the longitudinal direction when the second pin board tool is empty, the second pin board tool being configured such that the parallel pins in the second array are able to move freely in a longitudinal direction of the parallel pins in the second array independent of each other within a movement range when the second locking means are inactive, the second movement range being equal to or smaller than a length of each parallel pin in the second array;
upon detecting the object being placed against the second array causing one or more parallel pins in the second array to protrude, causing locking, using the second locking means, the second array of parallel pins in place to a second locking position;
causing 3D scanning a second pattern formed by the second array locked in the second locking position; and
causing 3D printing a second printed object having a second surface corresponding to the second pattern based on the second scanned pattern using the second pin board tool locked in the second locking position as a second print bed, wherein the first pattern and the second pattern correspond to opposite sides of the object.

40. A method according to claim 38, wherein the first printed object comprises a first thin layer of the one or more printing materials following the first pattern and having a nested, perforated or solid structure and the second printed object comprises a second thin layer of the one or more printing materials following the second pattern and having a nested, perforated or solid structure.

41. A method according to claim 39, wherein the object is a fractured part of a human body, the first printed object forms a first part of an orthopaedic cast and the second printed object forms a second part of the orthopaedic cast, the first part and the second part of the orthopaedic cast when brought together being able to substantially enclose the fractured part of the human body.
